(19) United States
(12) Patent Application Publication
(10) Pub. No.: US 2023/0095169 A1
(43) Pub. Date: Mar. 30, 2023

(54) THIN FILM TRANSISTOR SUBSTRATE, MANUFACTURING METHOD THEREOF, AND DISPLAY PANEL

(71) Applicant: SHENZHEN CHINA STAR OPTOELECTRONICS SEMICONDUCTOR DISPLAY TECHNOLOGY CO., LTD., Shenzhen (CN)

(72) Inventors: Shuning Zhao, Shenzhen (CN); Yuanjun Hsu, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 17/052,148

(22) PCT Filed: Sep. 3, 2020
(86) PCT No.: PCT/CN2020/113165

§ 371 Date: Oct. 30, 2020

(30) Foreign Application Priority Data
Aug. 10, 2020 (CN) 202010795044.3

(51) Int. Cl. H01L 29/786; H01L 27/12; H01L 29/66

(52) U.S. Cl. CPC H01L 29/78606; H01L 27/1225; H01L 29/78633; H01L 29/7869; H01L 27/127; H01L 29/66969

(57) ABSTRACT

A thin film transistor (TFT) substrate, a manufacturing method thereof, a display panel are disclosed. The TFT substrate includes: a substrate; an active layer disposed above the substrate and including a channel region, a source region, and a drain region, wherein the channel region is made of an oxide semiconductor, the source region and the drain region are made of a conductive oxide semiconductor; a gate insulating layer and a gate sequentially disposed on the channel region; a titanium oxide layer covering the source region and the drain region; and a source and a drain disposed above the titanium oxide layer.

### BACKGROUND OF INVENTION

### Field of Invention

The present application relates to the field of display technology, and in particular to a thin film transistor (TFT) substrate, a manufacturing method thereof, and a display panel.

### Description of Prior Art

Thin film transistors (TFTs) are currently the main driving element in liquid crystal display devices and active matrix OLED display devices, and are crucial to the development direction of high-performance flat panel displays. The thin film transistors have a variety of structures, including bottom-gate type and top-gate type. Compared with bottom-gate thin film transistors, top-gate thin film transistors do not have the problem of etching damage on a back channel, and have a gate insulating layer located on the active layer, which plays a protective role. The top-gate thin film transistors can be self-aligned by whole-surface exposure and dry etching, and have no overlap area, and their process is simple and compatible. A current method for realizing a self-aligned structure of the top-gate thin film transistor is that: an active layer includes a source region, a drain region, and a channel region, wherein after the source region and the drain region are self-aligned, the source region and the drain region are conducterized to serve as a source and a drain to reduce the resistivity. At present, the conducterizing method of the source region and the drain region mostly uses He or Ar plasma bombardment, which causes bonds between metals and oxygen to be broken, O atoms escape, increase oxygen vacancy of a semiconductor oxide, and improve conductivity of the source region and the drain region. However, the active layer, especially an IGZO layer, is very sensitive to surrounding environment, especially H atoms and O atoms. H atoms and O atoms will impact electrical properties of the thin film transistor devices, which will change the active layer from semiconductor to conductor, impacting characteristics and reliability of the thin film transistor devices.

### SUMMARY OF INVENTION

An object of the present application is to provide a thin film transistor (TFT) substrate, a manufacturing method thereof, and a display panel, that can prevent H atoms and O atoms from impacting electrical properties of the thin film transistor devices, and improve characteristics and reliability of the thin film transistor devices.

The present application provides a thin film transistor (TFT) substrate, including:

a substrate;

an active layer disposed above the substrate and including a channel region, a source region, and a drain region, wherein the channel region is made of an oxide semiconductor, the source region and the drain region are made of a conductive oxide semiconductor;

a gate insulating layer and a gate sequentially disposed on the channel region;

a titanium oxide layer covering the source region and the drain region; and

a source and a drain disposed above the titanium oxide layer, wherein the titanium oxide layer is provided with first via holes, and the source and the drain are in contact with the source region and the drain region through the first via holes, respectively.

Further, in some embodiments, the titanium oxide layer further covers the gate insulating layer and the gate.

Further, in some embodiments, the titanium oxide layer covers an entire surface of the substrate.

Further, in some embodiments, the TFT substrate further includes:

an interlayer dielectric layer disposed between the titanium oxide layer and the source and drain, wherein the first via holes penetrate the interlayer dielectric layer and the titanium oxide layer.

Further, in some embodiments, a thickness of the titanium oxide layer is 20 Å to 500 Å.

Further, in some embodiments, the oxide semiconductor is made of a material selected from one or more of indium gallium zinc oxide, indium gallium tin oxide, indium tin zinc oxide, and indium gallium zinc tin oxide.

Further, in some embodiments, the TFT substrate further includes a light-shielding layer disposed on the substrate corresponding to the active layer, wherein the light-shielding layer is made of metal, the interlayer dielectric layer is provided with a second via hole, the second via hole penetrates the interlayer dielectric layer, and the source is electrically connected to the light-shielding layer through the second via hole.

The present application also provides a method of manufacturing a thin film transistor (TFT) substrate, including the following steps:

providing a substrate;

forming an oxide semiconductor layer above the substrate, patterning the oxide semiconductor layer, defining a channel region on the patterned oxide semiconductor layer, and sequentially forming a gate insulating layer and a gate on the channel region;

forming a titanium layer on the substrate to cover regions at opposite sides of the channel region on the oxide semiconductor layer;

conductorizing the regions at opposite sides of the channel region on the oxide semiconductor layer, such that the regions at opposite sides of the channel region are conductorized to form a source region and a drain region, the oxide semiconductor layer is formed into an active layer, and the titanium layer is oxidized to form a titanium oxide layer; and

defining first via holes in the titanium oxide layer above the source region and the drain region, and forming a source and a drain above the titanium oxide layer, wherein the source and the drain are in contact with the source region and the drain region through the first via holes, respectively.

Further, in some embodiments, the step of forming the titanium layer on the substrate to cover regions at opposite sides of the channel region on the oxide semiconductor layer includes the following steps: patterning the titanium layer to remove portions of the titanium layer except for those on the regions at opposite sides of the channel region on the oxide semiconductor layer, the gate insulating layer, and the gate.

Further, in some embodiments, the titanium layer covers an entire surface of the substrate.

Further, in some embodiments, a thickness of the titanium layer is 20 Å to 500 Å.

Further, in some embodiments, before forming the source and the drain above the titanium oxide layer, the method of manufacturing the TFT substrate further includes the following steps:

forming an interlayer dielectric layer on the titanium oxide layer; and

providing first via holes through the titanium oxide layer and the interlayer dielectric layer above the source region and the drain region, wherein the source and the drain are in contact with the source region and the drain region through the first via holes, respectively.

Further, in some embodiments, before forming the oxide semiconductor layer, the method further includes a step of forming a metal layer on the substrate, and patterning the metal layer to form a light-shielding layer; and after forming the dielectric layer, the method further includes a step of providing a second via hole in the interlayer dielectric layer, wherein the second via hole penetrates the interlayer dielectric layer, and the source is in contact with the light-shielding layer through the second via hole.

The present application also provides a display panel, wherein the display panel includes the thin film transistor (TFT) substrate according to claim 1, and the TFT substrate includes:

the substrate;

the active layer disposed above the substrate and including the channel region, the source region, and the drain region, wherein the channel region is made of the oxide semiconductor, the source region and the drain region are made of the conductive oxide semiconductor;

the gate insulating layer and the gate sequentially disposed on the channel region;

the titanium oxide layer covering the source region and the drain region; and

the source and the drain disposed above the titanium oxide layer, wherein the titanium oxide layer is provided with first via holes, and the source and the drain are in contact with the source region and the drain region through the first via holes, respectively.

Further, in some embodiments, the titanium oxide layer further covers the gate insulating layer and the gate.

Further, in some embodiments, the titanium oxide layer covers an entire surface of the substrate.

Further, in some embodiments, the TFT substrate further includes:

an interlayer dielectric layer disposed between the titanium oxide layer and the source and drain, wherein the first via holes penetrate the interlayer dielectric layer and the titanium oxide layer.

Further, in some embodiments, a thickness of the titanium oxide layer is 20 Å to 500 Å.

Further, in some embodiments, the oxide semiconductor is made of a material selected from one or more of indium gallium zinc oxide, indium gallium tin oxide, indium tin zinc oxide, and indium gallium zinc tin oxide.

Further, in some embodiments, the TFT substrate further includes a light-shielding layer disposed on the substrate corresponding to the active layer, the light-shielding layer is made of metal, the interlayer dielectric layer is provided with a second via hole, the second via hole penetrates the interlayer dielectric layer, and the source is electrically connected to the light-shielding layer through the second via hole.

The present application provides a thin film transistor (TFT) substrate, a manufacturing method thereof, and a display panel. By adding a titanium layer to a TFT substrate, the titanium layer captures O atoms in an active layer during a conductorization process of a corresponding part of the active layer, and the titanium layer is oxidized while being conducterized, such that the oxidized titanium layer can effectively prevent changes in contents of H and O atoms in a layer there above from impacting the electrical properties of the thin film transistor.

### BRIEF DESCRIPTION OF DRAWINGS

The following detailed description of specific implementations of the present application in conjunction with the accompanying drawings will make the technical solutions and other beneficial effects of the present application obvious.

FIG. 1 is a schematic diagram showing a structure of a thin film transistor (TFT) substrate 100 provided in Embodiment 1 of the present application.

FIG. 2 is a schematic diagram showing a structure of a thin film transistor (TFT) substrate 200 provided in Embodiment 2 of the present application.

FIG. 3 is a schematic diagram showing a structure of a thin film transistor (TFT) substrate 300 provided in Embodiment 3 of the present application.

FIG. 4 is a flow chart showing a method of manufacturing a TFT substrate provided by the present application.

### DETAILED DESCRIPTION OF PREFERRED EMBODIMENTS

The technical solutions in the embodiments of the present application will be clearly and completely described in the following with reference to the accompanying drawings in the embodiments. It is apparent that the described embodiments are only a part of the embodiments of the present application, and not all of them. All other embodiments obtained by a person skilled in the art based on the embodiments of the present application without creative efforts are within the scope of the present application.

In order to make the purpose, technical solution, and effect of the present application clearer and more definite, the present application is further described in detail below with reference to the accompanying drawings and examples. It should be understood that the specific embodiments described herein are only used to explain the present application, and are not used to limit the present application.

The present application provides a thin film transistor (TFT) substrate, a manufacturing method thereof, and a display panel. The detailed description will be given below.

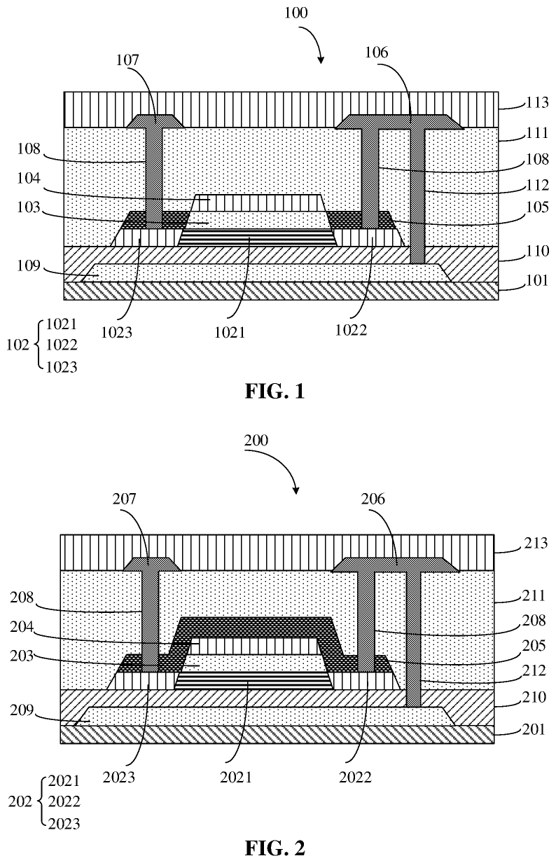

Referring to FIG. 1, which is a schematic structural diagram of a thin film transistor (TFT) substrate according to Embodiment 1 of the present application. In Embodiment 1 of the present application, a thin film transistor (TFT) substrate 100 is provided, including a substrate 101. The substrate 101 may be a glass substrate or a flexible substrate, such as a polyimide substrate.

An active layer 102 is disposed above the substrate 101; the active layer 102 includes a channel region 1021, a source region 1022 and a drain region 1023; material of the channel region 1021 includes an oxide semiconductor, and material of the source region 1022 and the drain region 1023 includes a conductive oxide semiconductor. The oxide semiconductor may be indium gallium zinc oxide (IGZO), indium gallium tin oxide (IGTO), indium tin zinc oxide (ITZO), or indium gallium zinc tin oxide (IGZTO), etc., and which is not particularly limited herein. The conductive oxide semiconductor refers to a material obtained after the aforementioned oxide semiconductor is subjected to a conducterization treatment. A thickness of the active layer 102 ranges from 100 Å to 1000 Å.

A gate insulating layer 103 and a gate 104 are sequentially disposed on the channel region 1021. the gate insulating layer 103 may be made of a material including silicon nitride or silicon oxide, and have a thickness of 800 A to 3000 A. The gate 104 may be made of a material including Mo/Cu, Ti/Cu, Mo/Al/Mo, Al/Mo or Mo/Ti/Cu, and have a thickness of 100 Å to 1000 Å.

A titanium oxide layer 105 covers the source region 1022 and the drain region 1023, and a thickness of the titanium oxide layer 105 ranges from 20 Å to 500 Å. The source 106 and the drain 107 are disposed above the titanium oxide layer 105. The material of the source 106 and the drain 107 can be Mo/Cu, Ti/Cu, Mo/Al/Mo, Al/Mo or Mo/Ti/Cu. First via holes 108 are provided on the titanium oxide layer 105, and the source 106 and the drain 107 are in contact with the source region 1022 and the drain region 1023 through the first via holes 108, respectively.

The TFT substrate 100 further includes the elements as follows:

A light-shielding layer 109 is disposed on the substrate 101, an area of the light-shielding layer 109 is larger than an area of the active layer 102, and an orthographic projection of the light-shielding layer 109 on the substrate 101 covers an orthographic projection of the active layer 102 on the substrate 101, so that the light-shielding layer 109 can completely shield the active layer 102, which can prevent the active layer 102 from being irradiated by light to cause negative drift of a threshold voltage of the TFT. The light-shielding layer 109 can be a single-layered film or a double-layered film, and made of a material selected from one or an alloy formed by a combination of two or more of Mo, Al, Cu, and Ti, with a thickness of 500 Å to 2000 Å.

A buffer layer 110 is disposed on the substrate 101 and covers the light-shielding layer 109. Specifically, the buffer layer 110 may be a single-layered or multiple-layered silicon nitride or silicon oxide with a thickness of 1000 Å to 5000 Å.

An interlayer dielectric layer 111 is disposed between the titanium oxide layer 105 and the source 106 and the drain 107, and the first via holes 108 penetrate the interlayer dielectric layer 111 and the titanium oxide layer 105. The interlayer dielectric layer 111 may be a SiOx film with a thickness ranging from 2000 Å to 10000 Å.

The buffer layer 110 and the interlayer dielectric layer 111 are provided with a second via hole 112, and the second via hole 112 penetrates the buffer layer 110 and the interlayer dielectric layer 111. The source 106 is in contact with the light-shielding layer 109 through the second via hole 112. The second via hole 112 is located at a side of the first via holes 108 away from the channel region 1021.

A passivation layer 113 is disposed on the interlayer dielectric layer 111 and covers the source 106 and the drain 107. The passivation layer 113 can be made of silicon nitride or silicon oxide, and a thickness of the passivation layer 113 is 1000 Å to 5000 Å.

The present application provides a thin film transistor (TFT) substrate with a top-gate self-aligned structure. The source region 1022 and the drain region 1023 on the active layer 102 are covered with a titanium oxide layer 105, the titanium oxide layer 105, the gate insulating layer 103, and the gate 104 can effectively prevent H and O atoms in a layer there above, such as the interlayer dielectric layer 111, from impacting the active layer. The titanium oxide layer 105 of high-density covers the source region 1022 and the drain region 1023, and is in close contact with the gate insulating layer 103 above the channel region 1021, which protects the opposite sides of the channel region and improves the electrical stability and reliability of the TFT substrate.

Referring to FIG. 2, which is a schematic structural diagram of a thin film transistor (TFT) substrate 200 according to Embodiment 2 of the present application. In the present application, the structure of the TFT substrate 200 provided in Embodiment 2 and the structure of the TFT substrate 100 provided in Embodiment 1 are substantially the same except for the structure of the titanium oxide layer 205.

In this embodiment, the TFT substrate 200 includes the elements as follows:

A substrate 201 is provided.

An active layer 202 is disposed above the substrate 201, wherein the active layer 202 includes a channel region 2021, a source region 2022, and a drain region 2023.

A gate insulating layer 203 and a gate 204 are sequentially disposed above the channel region 2021.

A titanium oxide layer 205 covers the active layer 202, and the gate insulating layer 203 and the gate 204 above the active layer 202. Specifically, the titanium oxide layer 205 in the TFT substrate 200 of this embodiment covers the source region 2022 and the drain region 2023, and further covers the gate insulating layer 203 and the gate 204 above the channel region 2021. As such, in addition to providing a titanium oxide layer 205 in the source region 2022 and the drain region 2023 to protect these regions, more protection for the channel region 2021 is further provided, and changes in contents of H and O atoms in a layer there above can be more effectively prevented from impacting the electrical conductivity of the active layer 202, thereby not only improving the electrical stability of the source region 2022 and the drain region 2023 as conductors, but also preventing the channel region 2021 from changing from a semiconductor to a conductor, thus improving application reliability of the TFT substrate 200.

A source 206 and a drain 207 are disposed above the titanium oxide layer 205. First via holes 208 are provided on the titanium oxide layer 205, and the source 206 and the drain 207 are in contact with the source region 2022 and the drain region 2023 through the first via holes 208, respectively.

The TFT substrate 200 further includes the elements as follows:

A light-shielding layer 209 is disposed on the substrate 201, an area of the light-shielding layer 209 is larger than an area of the active layer 202, and an orthographic projection of the light-shielding layer 209 on the substrate 201 covers an orthographic projection of the active layer 202 on the substrate 201.

A buffer layer 210 is disposed on the substrate 201 and covers the light-shielding layer 209.

An interlayer dielectric layer 211 is disposed between the titanium oxide layer 205 and the source 206 and the drain 207. First via holes 208 penetrates the interlayer dielectric layer 211 and the titanium oxide layer 205.

A buffer layer 210 and an interlayer dielectric layer 211 are provided with a second via hole 212, and the second via hole 212 penetrates the buffer layer 210 and the interlayer dielectric layer 211. The source 206 is in contact with the light-shielding layer 209 through the second via hole 212. The second via hole 212 is located at a side of the first via holes 208 away from the channel region 2021.

A passivation layer 213 is disposed on the interlayer dielectric layer 211 and covers the source 206 and the drain 207.

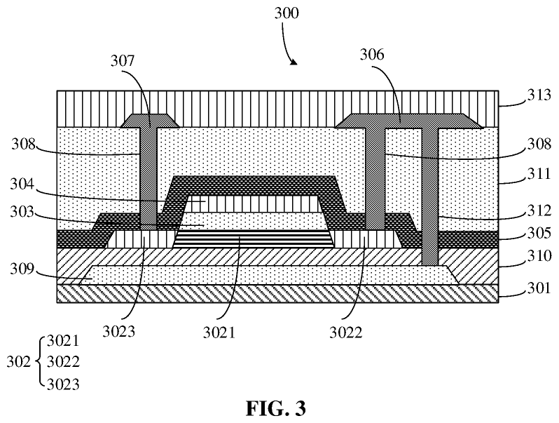

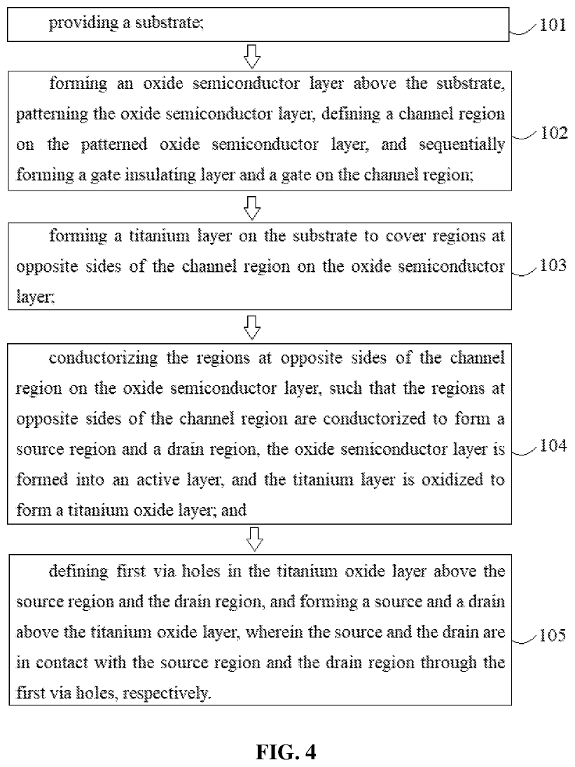

Referring to FIG. 3, which is a schematic structural diagram of a thin film transistor (TFT) substrate 300 according to Embodiment 3 of the present application. In the present application, the structure of the TFT substrate 300 provided in Embodiment 3 and the structure of the TFT substrate 100 provided in Embodiment 1 are substantially the same except for the structure of the titanium oxide layer 305 and a connection manner of the source 306 and the light-shielding layer 309.

In this embodiment, the TFT substrate 300 includes the elements as follows:

A substrate 301 is provided.

An active layer 3202 is disposed above the substrate 301, wherein the active layer 202 includes a channel region 3021, a source region 3022, and a drain region 3023.

A gate insulating layer 303 and a gate 304 are sequentially disposed above the channel region 3021.

A titanium oxide layer 305 covers the active layer 302, and the gate insulating layer 303 and the gate 304 above the active layer 302. Specifically, the titanium oxide layer 305 in the TFT substrate 300 of this embodiment not only covers the active layer 302, and the gate insulating layer 303 and gate 304 on the active layer 302, but also covers the substrate 301 and in direct contact with the substrate 301. The titanium oxide layer 305 of the present embodiment can not only prevent the H atoms and O atoms of a layer there above from impacting the electrical properties of the thin film transistor device, but also function as an interlayer dielectric layer. Due to the high density and insulation of the titanium oxide layer 305, the titanium oxide layer 305 covering the substrate 301 can be used as a dielectric layer. Therefore, in other embodiments, the TFT substrate may not be provided with an interlayer dielectric layer, saving one preparation process.

The source 306 and the drain 307 are disposed above the titanium oxide layer 305. The first via holes 308 are provided on the titanium oxide layer 305, and the source 306 and the drain 307 are in contact with the source region 3022 and the drain region 3023 through the first via holes 308, respectively.

The TFT substrate 300 also includes the elements as follows:

A light-shielding layer 309 is disposed on the substrate 301, an area of the light-shielding layer 309 is larger than an area of the active layer 302, and an orthographic projection of the light-shielding layer 309 on the substrate 301 covers an orthographic projection of the active layer 302 on the substrate 301.

A buffer layer 310 is disposed on the substrate 301 and covers the light-shielding layer 309.

An interlayer dielectric layer 311 is disposed between the titanium oxide layer 305 and the source 306 and the drain 307, and the first via holes 308 penetrate the interlayer dielectric layer 311 and the titanium oxide layer 305.

A buffer layer 310, a titanium oxide layer 305, and an interlayer dielectric layer 311 are provided with a second via hole 312, and the second via hole 312 penetrates the buffer layer 310, the titanium oxide layer 305 and the interlayer dielectric layer 311. The source 306 is in contact with the light-shielding layer 309 through the second via hole 312.

A passivation layer 313 is disposed on the interlayer dielectric layer 311 and covers the source 306 and the drain 307.

Referring to FIG. 4, which is a schematic flow chart of a method of manufacturing the aforementioned TFT substrate. Referring to FIG. 1 to FIG. 3. The manufacturing method includes the following steps:

Step 101: providing a substrate, forming a light-shielding layer on the substrate, and forming a buffer layer covering the light-shielding layer on the substrate.

Specifically, the light-shielding layer is prepared by depositing one or two layers of metal film on the substrate, a thickness of the metal film is between 500 Å to 2000 Å, and material of the metal film may be one or an alloy formed by a combination of two or more of Mo, Al, Cu, and Ti. Depositing silicon nitride or silicon oxide on the substrate serves as a buffer layer, and the overall thickness of the buffer layer is 1000 Å to 5000 Å.

Step 102: forming an oxide semiconductor layer on the buffer layer, patterning the oxide semiconductor layer, defining a channel region on the patterned oxide semiconductor layer, and sequentially forming a gate insulating layer and a gate on the channel region.

Specifically, an oxide semiconductor layer is deposited on the buffer layer, and the oxide semiconductor layer is patterned so that the oxide semiconductor layer corresponds to the light-shielding layer, and an orthographic projection of the light-shielding layer on the substrate covers an orthographic projection of the oxide semiconductor layer on the substrate. A channel region is defined on the patterned oxide semiconductor layer, silicon nitride or silicon oxide is deposited on the patterned oxide semiconductor layer to serve as a gate insulating layer, and then a metal layer is deposited on the gate insulating layer to serve as a gate. The gate insulating layer and the gate are prepared through photolithography by etching to obtain a pattern of the gate first, which corresponds to the channel region, followed by self-alignment of the gate, and etching the gate insulating layer, wherein the gate insulating layer only under the gate is reserved, and the remaining part of the gate insulating layer material is etched away.

Step 103: forming a titanium layer on the substrate.

Specifically, a titanium layer is deposited on the substrate by chemical vapor deposition (CVD). Due to process limitation, a thickness of the titanium layer should be greater than 20 Å; if it is too thick, the titanium layer will not be completely oxidized during the subsequent oxidation process, so the thickness of the titanium layer is less than 500 Å. It is worth noting that such formation includes two steps of deposition and patterning.

In this embodiment, the titanium layer is deposited on the substrate and covers the oxide semiconductor layer, the gate insulating layer, and the gate.

In some embodiments, after depositing a titanium layer on the substrate, the titanium layer may further need to be patterned o remove portions of the titanium layer except for those on the regions at opposite sides of the channel region on the oxide semiconductor layer, the gate insulating layer, and the gate, such that the titanium layer only covers the oxide semiconductor layer, the gate insulating layer, and the gate.

In some embodiments, in addition to etching away the titanium layer directly in contact with the substrate, the titanium layer covering the gate may also be removed.

Step 104: conductorizing the regions at opposite sides of the channel region on the oxide semiconductor layer, such that the regions at opposite sides of the channel region are conductorized to form a source region and a drain region, the oxide semiconductor layer is formed into an active layer, and the titanium layer is oxidized to form a titanium oxide layer.

Specifically, the conducterization treatment includes high temperature annealing treatment. In an oxygen-containing atmosphere, such as in a mixed gas of O2 and Ar, the titanium layer is annealed at a high temperature. During the oxidation of the titanium layer, O atoms at opposite sides of the channel region on the oxide semiconductor layer are deprived to make opposite sides of the channel region have a reduced oxygen content and become a conductor, thereby forming a source region and a drain region. On the other hand, the channel region of the oxide semiconductor layer is protected by the gate insulating layer and the gate, and its oxygen content remains unchanged, such that it remains to be a semiconductor. The oxide semiconductor layer forms the active layer of the TFT substrate. After the titanium layer captures O atoms, it is oxidized to form a titanium oxide layer, which can block the influence of changes in the content of H atoms and O atoms in the upper film layer, such as the interlayer dielectric layer, on the active layer.

Step 105: forming an interlayer dielectric layer on the titanium oxide layer; providing first via holes in the titanium oxide layer and the interlayer dielectric layer above the source region and the drain region; and forming a source and a drain above the interlayer dielectric layer, wherein the source and the drain are respectively in contact with the source region and the drain region through the first via holes.

Specifically, silicon nitride or silicon oxide is deposited on the buffer layer to cover the titanium oxide layer, the gate insulating layer, and the gate, to serve as an interlayer dielectric layer. One photolithography process is used to etch both the interlayer dielectric layer and the titanium oxide layer above the source region and the drain region to form two penetrating first via holes. All the buffer layer, the titanium oxide layer, and the interlayer dielectric layer are etched using one photolithography process, and a penetrating second via hole is formed on the buffer layer, the titanium oxide layer, and the interlayer dielectric layer. The second via hole is located on a side of the first via holes away from the channel region.

A metal layer is deposited on the interlayer dielectric layer and patterned to serve as a source and a drain. The source and the drain are in contact and connected with the source region and the drain region through the first via holes, respectively. The source is connected to the light-shielding layer through the second via hole to realize signal communication of the light-shielding layer.

Finally, an inorganic film layer is deposited on the source and the drain to serve as a passivation layer.

In the method of manufacturing a thin film transistor (TFT) substrate provided in the present application, a titanium layer is formed on a substrate, and the titanium layer covers the regions at opposite sides of the channel region on the oxide semiconductor layer. After high temperature annealing treatment, the titanium layer takes oxygen atoms in the oxide semiconductor layer, and a titanium oxide layer is formed on the conducterized part while the corresponding part of the oxide semiconductor layer is conducterized. The titanium oxide layer can prevent H atoms and O atoms in a layer there above from impacting electrical properties of the active layer. As such, the method can realize the conductorization of the corresponding part of the active layer without increasing the complexity of the process and improve the reliability of the TFT substrate.

The present application also provides a display panel including the aforementioned TFT substrate.

In the above embodiments, the descriptions of each embodiment have their own emphasis. The parts that are not described in detail in an embodiment can be referred to the detailed descriptions in other embodiments above, which will not be repeated herein for brevity.

The thin film transistor (TFT) substrate, the manufacturing method thereof, and the display panel provided in the embodiments of the present application have been described in detail above. Specific examples are used in this document to explain the principles and implementation of the present invention. The descriptions of the above embodiments are only for understanding the method of the present invention and its core ideas, to help understand the technical solution of the present application and its core ideas, and a person of ordinary skill in the art should understand that it can still modify the technical solution described in the foregoing embodiments, or equivalently replace some of the technical features. Such modifications or replacements do not depart the spirit of the corresponding technical solutions beyond the scope of the technical solutions of the embodiments of the present application.

What is claimed is:

1. A thin film transistor (TFT) substrate, comprising:
a substrate;
an active layer disposed above the substrate and comprising a channel region, a source region, and a drain region, wherein the channel region is made of an oxide semiconductor, the source region and the drain region are made of a conductive oxide semiconductor;
a gate insulating layer and a gate sequentially disposed on the channel region;
a titanium oxide layer covering the source region and the drain region; and
a source and a drain disposed above the titanium oxide layer, wherein the titanium oxide layer is provided with first via holes, and the source and the drain are in contact with the source region and the drain region through the first via holes, respectively.

2. The TFT substrate according to claim 1, wherein the titanium oxide layer further covers the gate insulating layer and the gate.

3. The TFT substrate according to claim 1, wherein the titanium oxide layer covers an entire surface of the substrate.

4. The TFT substrate according to claim 1, further comprising:
an interlayer dielectric layer disposed between the titanium oxide layer and the source and drain, wherein the first via holes penetrate the interlayer dielectric layer and the titanium oxide layer.

5. The TFT substrate according to claim 1, wherein a thickness of the titanium oxide layer is 20 Å to 500 Å.

6. The TFT substrate according to claim 1, wherein the oxide semiconductor is made of a material selected from one or more of indium gallium zinc oxide, indium gallium tin oxide, indium tin zinc oxide, and indium gallium zinc tin oxide.

7. The TFT substrate according to claim 4, further comprising a light-shielding layer disposed on the substrate corresponding to the active layer, wherein the light-shielding layer is made of metal, the interlayer dielectric layer is provided with a second via hole, the second via hole penetrates the interlayer dielectric layer, and the source is electrically connected to the light-shielding layer through the second via hole.

8. A method of manufacturing a thin film transistor (TFT) substrate, comprising the following steps:
providing a substrate;
forming an oxide semiconductor layer above the substrate, patterning the oxide semiconductor layer, defining a channel region on the patterned oxide semiconductor layer, and sequentially forming a gate insulating layer and a gate on the channel region;
forming a titanium layer on the substrate to cover regions at opposite sides of the channel region on the oxide semiconductor layer;
conductorizing the regions at opposite sides of the channel region on the oxide semiconductor layer, such that the regions at opposite sides of the channel region are conductorized to form a source region and a drain region, the oxide semiconductor layer is formed into an active layer, and the titanium layer is oxidized to form a titanium oxide layer; and
defining first via holes in the titanium oxide layer above the source region and the drain region, and forming a source and a drain above the titanium oxide layer, wherein the source and the drain are in contact with the source region and the drain region through the first via holes, respectively.

9. The method of manufacturing the TFT substrate according to claim 8, wherein the step of forming the titanium layer on the substrate to cover regions at opposite sides of the channel region on the oxide semiconductor layer comprises the following steps:
patterning the titanium layer to remove portions of the titanium layer except for those on the regions at opposite sides of the channel region on the oxide semiconductor layer, the gate insulating layer, and the gate.

10. The method of manufacturing the TFT substrate according to claim 8, wherein the titanium layer covers an entire surface of the substrate.

11. The method of manufacturing the TFT substrate according to claim 8, wherein a thickness of the titanium layer is 20 Å to 500 Å.

12. The method of manufacturing the TFT substrate according to claim 8, before forming the source and the drain above the titanium oxide layer, further comprising the following steps:
forming an interlayer dielectric layer on the titanium oxide layer; and
providing first via holes through the titanium oxide layer and the interlayer dielectric layer above the source region and the drain region, wherein the source and the drain are in contact with the source region and the drain region through the first via holes, respectively.

13. The method of manufacturing the TFT substrate according to claim 12, wherein before forming the oxide semiconductor layer, the method further comprises a step of forming a metal layer on the substrate, and patterning the metal layer to form a light-shielding layer; and after forming the dielectric layer, the method further comprises a step of providing a second via hole in the interlayer dielectric layer, wherein the second via hole penetrates the interlayer dielectric layer, and the source is in contact with the light-shielding layer through the second via hole.

14. A display panel, wherein the display panel comprises the thin film transistor (TFT) substrate according to claim 1, and the TFT substrate comprises:
the substrate;
the active layer disposed above the substrate and comprising the channel region, the source region, and the drain region, wherein the channel region is made of the oxide semiconductor, the source region and the drain region are made of the conductive oxide semiconductor;
the gate insulating layer and the gate sequentially disposed on the channel region;
the titanium oxide layer covering the source region and the drain region; and
the source and the drain disposed above the titanium oxide layer, wherein the titanium oxide layer is provided with first via holes, and the source and the drain are in contact with the source region and the drain region through the first via holes, respectively.

15. The display panel according to claim 14, wherein the titanium oxide layer further covers the gate insulating layer and the gate.

16. The display panel according to claim 14, wherein the titanium oxide layer covers an entire surface of the substrate.

17. The display panel according to claim 14, wherein the TFT substrate further comprises:
an interlayer dielectric layer disposed between the titanium oxide layer and the source and drain, wherein the first via holes penetrate the interlayer dielectric layer and the titanium oxide layer.

18. The display panel according to claim 14, wherein a thickness of the titanium oxide layer is 20 Å to 500 Å.

19. The display panel according to claim 14, wherein the oxide semiconductor is made of a material selected from one or more of indium gallium zinc oxide, indium gallium tin oxide, indium tin zinc oxide, and indium gallium zinc tin oxide.

20. The display panel according to claim 14, wherein the TFT substrate further comprises a light-shielding layer disposed on the substrate corresponding to the active layer, the light-shielding layer is made of metal, the interlayer dielectric layer is provided with a second via hole, the second via hole penetrates the interlayer dielectric layer, and the source is electrically connected to the light-shielding layer through the second via hole.
